(19) United States
(12) Patent Application Publication
(10) Pub. No.: US 2025/0311430 A1
(43) Pub. Date: Oct. 2, 2025

(54) STRETCHABLE PIXEL ARRAY SUBSTRATE

(71) Applicant: AUO Corporation, Hsinchu City (TW)

(72) Inventors: Kent-Yi Lee, Hsinchu City (TW); Wen-Ting Wang, Hsinchu City (TW); Jia-Hao Du, Hsinchu City (TW); Chia-Kai Chen, Hsinchu City (TW); Cheng-Liang Wang, Hsinchu City (TW)

(73) Assignee: AUO Corporation, Hsinchu City (TW)

(21) Appl. No.: 18/945,560

(22) Filed: Nov. 13, 2024

(30) Foreign Application Priority Data
Apr. 1, 2024 (TW) 113112378

(51) Int. Cl. H01L 27/12; H01L 27/15

(52) U.S. Cl. CPC H10D 86/60; H10D 86/421; H10H 29/142

(57) ABSTRACT

A stretchable pixel array substrate includes a base, pixel structures and a gate driving circuit. An active area of the base has openings to define first islands, second islands and first bridges. The first islands of the active area of the base, the second islands of the active area of the base, the first bridges of the active area of the base, the pixel structures and the gate driving circuit include structural units. Each of the structural unit includes a first island, a second island adjacent to the first island, a first bridge, p pixel structures of the pixel structures disposed on the first island and the second island, and a driving transistors of the gate driving circuit disposed on the first island. A driving transistor of the gate driving circuit and a pixel transistor of at least one of the p pixel structures are disposed on the first island.

### CROSS-REFERENCE TO RELATED APPLICATION

This application claims the priority benefit of Taiwan application serial no. 113112378, filed on Apr. 1, 2024. The entirety of the above-mentioned patent application is hereby incorporated by reference herein and made a part of this specification.

### BACKGROUND

### Technical Field

The disclosure relates to a pixel array substrate, and in particular to a stretchable pixel array substrate.

### Description of Related Art

With the rapid development of electronic technology, electronic products are constantly being introduced. In order to enable electronic products to be used in various fields, the characteristics of stretchability, thinness, and unlimited appearance are gradually receiving attention. In other words, electronic products are gradually required to have different appearances according to different application methods and application environments, so electronic products need to be stretchable.

However, when electronic products are stretched, they may suffer structural fractures due to stress, and may even cause internal circuit breakage. Therefore, how to make stretchable electronic products with good manufacturing yield and product reliability is an issue that needs to be solved urgently.

### SUMMARY

This disclosure provides a stretchable pixel array substrate with good stretchability.

A stretchable pixel array substrate of this disclosure includes a base, pixel structures and a gate driving circuit. The base has an active area. The active area has openings to define first islands, second islands and first bridges of the active area. An area of each of the first islands is larger than an area of each of the second islands. At least one part of the first bridges is connected between the first islands and the second islands. The pixel structures are disposed on the active area of the base. Each of the pixel structures includes a pixel transistor and a light emitting element electrically connected to the pixel transistor. The gate driving circuit is disposed on the active area and electrically connected to the pixel structures. The first islands of the active area of the base, the second islands of the active area of the base, the first bridges of the active area of the base, the pixel structures and the gate driving circuit includes structural units. Each of the structural unit includes a first island, a second island adjacent to the first island, a first bridge connecting between the first island and the second island, p pixel structures of the pixel structures disposed on the first island and the second island and a driving transistor at least disposed in the gate driving circuit of the first island, p is a positive integer, 1≤p≤6, and the driving transistor of the gate driving circuit and the pixel transistor of at least one pixel structure of the p pixel structures are disposed on the first island.

### BRIEF DESCRIPTION OF THE DRAWINGS

FIG. 1 is a schematic top view of a display panel according to an embodiment of the present disclosure.

FIG. 2 is a schematic top view of part R of the stretchable pixel array substrate 10 according to an embodiment of this disclosure.

FIG. 3 is a top view and enlarged schematic diagram of a stretchable pixel array substrate 10 according to an embodiment of this disclosure.

FIG. 4 and FIG. 5 are schematic cross-sectional views of a stretchable pixel array substrate 10 according to an embodiment of this disclosure.

FIG. 6 is a top view of a part of the stretchable pixel array substrate 10A according to another embodiment of the present disclosure.

FIG. 7 is a top view of a part of the stretchable pixel array substrate 10B according to another embodiment of the present disclosure.

FIG. 8 is a three-dimensional schematic diagram of a stretchable pixel array substrate 10C according to yet another embodiment of the present disclosure.

FIG. 9 is a three-dimensional schematic diagram of a stretchable pixel array substrate 10D according to an embodiment of this disclosure.

FIG. 10 is a three-dimensional schematic diagram of a stretchable pixel array substrate 10E according to another embodiment of the present disclosure.

FIG. 11 is a three-dimensional schematic diagram of a stretchable pixel array substrate 10F according to another embodiment of the present disclosure.

FIG. 12 is a schematic top view of a part R of the stretchable pixel array substrate 10F according to another embodiment of the present disclosure.

FIG. 13 is a top view of a part of the stretchable pixel array substrate 10G according to yet another embodiment of this disclosure.

FIG. 14 is a schematic cross-sectional view of a stretchable pixel array substrate 10G according to yet another embodiment of this disclosure.

FIG. 15 is a top view of a part of the stretchable pixel array substrate 10H according to an embodiment of this disclosure.

FIG. 16 is a top view of a part of a stretchable pixel array substrate 10I according to another embodiment of the present disclosure.

FIG. 17 is a schematic cross-sectional view of a stretchable pixel array substrate 10I according to another embodiment of the present disclosure.

### DESCRIPTION OF THE EMBODIMENTS

Reference will now be made in detail to exemplary embodiments provided in the disclosure, examples of which are illustrated in accompanying drawings. Wherever possible, identical reference numerals are used in the drawings and descriptions to refer to identical or similar parts.

It should be understood that when a device such as a layer, film, region or substrate is referred to as being “on” or “connected to” another device, it may be directly on or connected to another device, or intervening devices may also be present. In contrast, when a device is referred to as being “directly on” or “directly connected to” another device, there are no intervening devices present. As used herein, the term “connected” may refer to physical connection and/or electrical connection. Besides, if two devices are “electrically connected” or “coupled”, it is possible that other devices are present between these two devices.

The term “about,” “approximately,” or “substantially” as used herein is inclusive of the stated value and a mean within an acceptable range of deviation for the particular value as determined by people having ordinary skill in the art, considering the measurement in question and the error associated with measurement of the particular quantity (i.e., the limitations of the measurement system). For example, “about” may mean within one or more standard deviations, for example, ±30%, ±20%, ±10%, or ±5% of the stated value. Moreover, a relatively acceptable range of deviation or standard deviation may be chosen for the term “about,” “approximately,” or “substantially” as used herein based on optical properties, etching properties or other properties, instead of applying one standard deviation across all the properties.

Unless otherwise defined, all terms (including technical and scientific terms) used herein have the same meaning as commonly understood by people of ordinary skill in the art. It will be further understood that terms, such as those defined in the commonly used dictionaries, should be interpreted as having a meaning that is consistent with their meaning in the context of the relevant art and the invention and will not be interpreted in an idealized or overly formal sense unless expressly so defined herein.

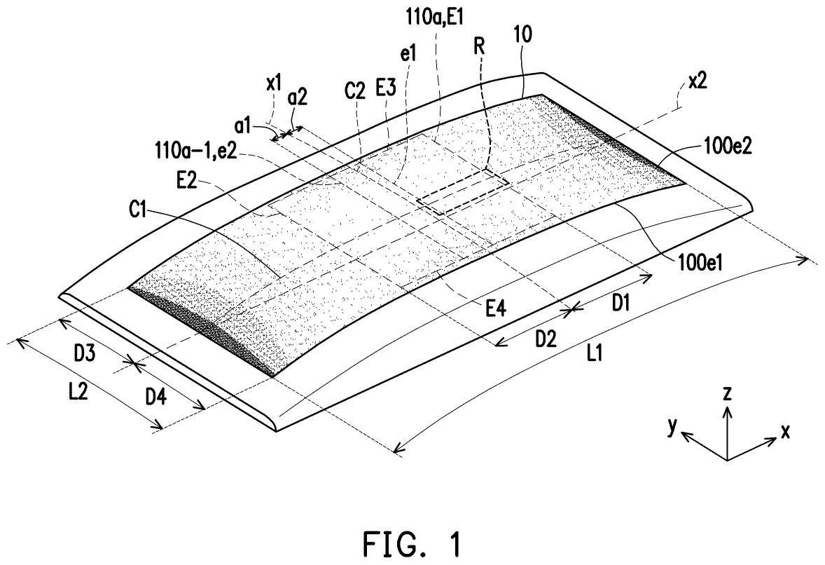

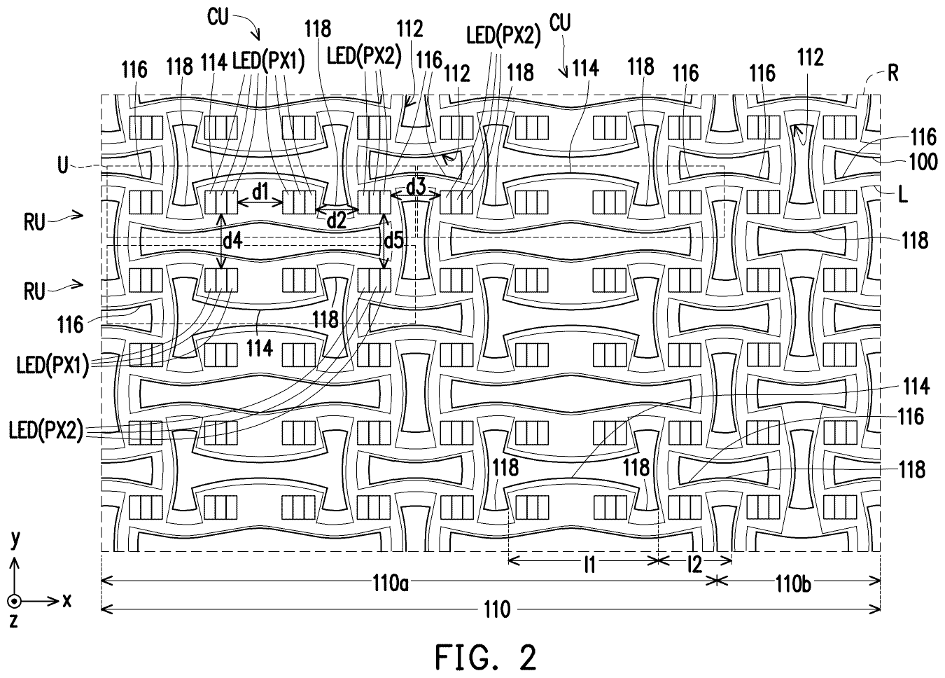

FIG. 1 is a three-dimensional schematic diagram of a stretchable pixel array substrate 10 according to an embodiment of this disclosure. In particular, FIG. 1 shows the stretchable pixel array substrate 10 in a curved state and the stress distribution thereon. The denser the points, the greater the stress thereon, and the sparser the points, the smaller the stress thereon. FIG. 2 is a schematic top view of part R of the stretchable pixel array substrate 10 according to an embodiment of this disclosure. FIG. 2 corresponds to part R of FIG. 1.

Referring to FIG. 1 and FIG. 2, the stretchable pixel array substrate 10 includes a base 100 having an active area 110. The active area 110 of the base 100 has openings 112 to define first islands 114, second islands 116 and first bridges 118 of the active area 110. An area of each of the first islands 114 is larger than an area of each of the second islands 116. At least a portion of the first bridges 118 are connected between the first islands 114 and the second islands 116.

In some embodiments, the active area 110 includes a first stress sub-region 110a and a second stress sub-region 110b, wherein when the stretchable pixel array substrate 10 is bent, a stress on the first stress sub-region 110a is smaller than a stress on the second stress sub-region 110b, the first stress sub-region 110a with a smaller stress on it has the first islands 114, a part of the second islands 116 and a part of the first bridges 118, and the second stress sub-region 110b with larger stress on it has another part of the second islands 116 and another part of the first bridges 118.

A first direction x and a second direction y are staggered, and a third direction z is perpendicular to the first direction x and the second direction y. For example, in some embodiments, the stretchable pixel array substrate 10 is bent in the first direction x and the second direction y, and the stretchable pixel array substrate 10 is cut out by the xz plane where the first direction x and the third direction z are located to obtain a first cut line C1, the first cut line C1 has a first radius of curvature and convex towards the third direction z, the stretchable pixel array substrate 10 is cut out by the yz plane where the second direction y and the third direction z are located to obtain a second cut line C2. The second cut line C2 has a second radius of curvature and convex toward the third direction z, and the first radius of curvature is larger than the second radius of curvature. However, this disclosure is not limited to thereto. In other embodiments, the stretchable pixel array substrate 10 may be bent in other ways.

In some embodiments, the base 100 of the stretchable pixel array substrate 10 has a first central axis x1, a first direction x is intersected with the first central axis x1, the base 100 has a first width L1 in the first direction x, and the active area 110 includes a first stress sub-region 110 a having first islands 114, a first stress sub-region 110a has a first boundary E1 and a second boundary E2 opposite to each other. The first boundary E1 and the second boundary E2 are located on opposite sides of the first central axis x1 respectively. The distance D1 between the first boundary E1 and the first central axis x1 of the first stress sub-region 110a in the first direction x is less than or equal to one-quarter of the first width L1, and the distance D2 between the second boundary E2 of the first stress sub-region 110a and the first central axis x1 in the first direction x is less than or equal to one-quarter of the first width L1.

In some embodiments, the base 100 of the stretchable pixel array substrate 10 has a second central axis x2, the second direction y is intersected with the second central axis x2, the base 100 has a second width L2 in the second direction y, and the active area 110 includes a first stress sub-region 110a, the first stress sub-region 110a also has a third boundary E3 and a fourth boundary E4 opposites to each other. The third boundary E3 and the fourth boundary E4 are located on opposite sides of the second central axis x2 respectively. A distance D3 in the second direction y between the third boundary E3 of the first stress sub-region 110a and the second central axis x2 is less than or equal to half of the second width L2, and the distance D4 in the second direction y between the fourth boundary E4 of the first stress sub-region 110a and the second central axis x2 is less than or equal to one-quarter of the second width L2. In some embodiments, the first stress sub-region 110a may be a rectangular region, and multiple boundaries of the rectangular region are respectively parallel to two adjacent edges 100e1, 100e2 of the base 100. However, this disclosure is not limited to thereto. In other embodiments, the first stress sub-region 110a with smaller stress on the stretchable pixel array substrate 10 may be other shapes and/or sizes, depending on the bending method of the stretchable pixel array substrate 10 and/or the degree of bending of the stretchable pixel array substrate 10.

For example, in some embodiments, a material of base 100 may include polyimide (PI), polyethylene naphthalate (PEN), polyethylene terephthalate (polyethylene terephthalate); PET), polycarbonates (PC), polyether sulfone (PES) or polyarylate (polyarylate), other suitable materials or a combination of at least two of the aforementioned materials, but this disclosure is not limited to thereto.

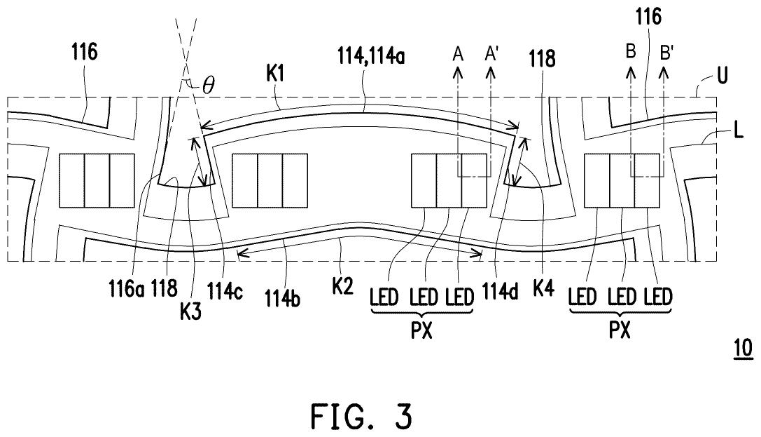

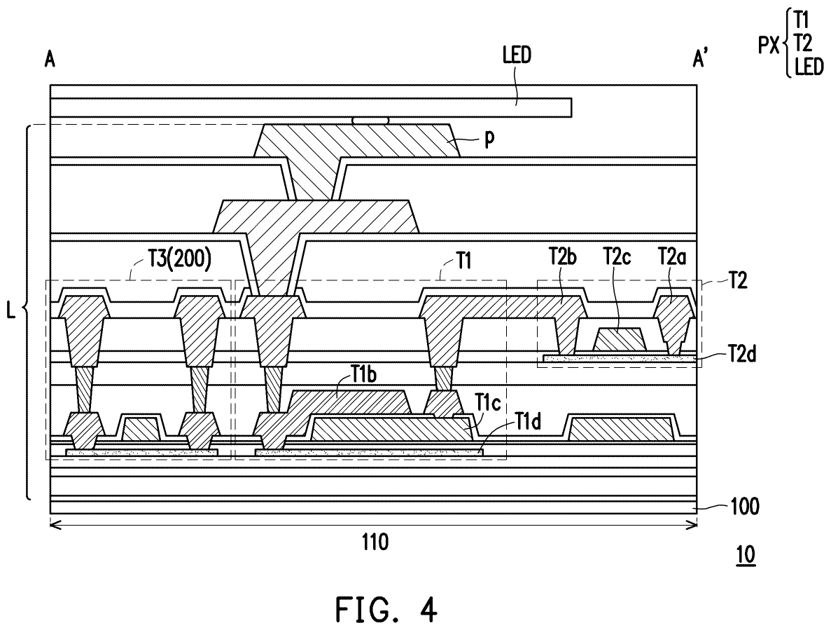

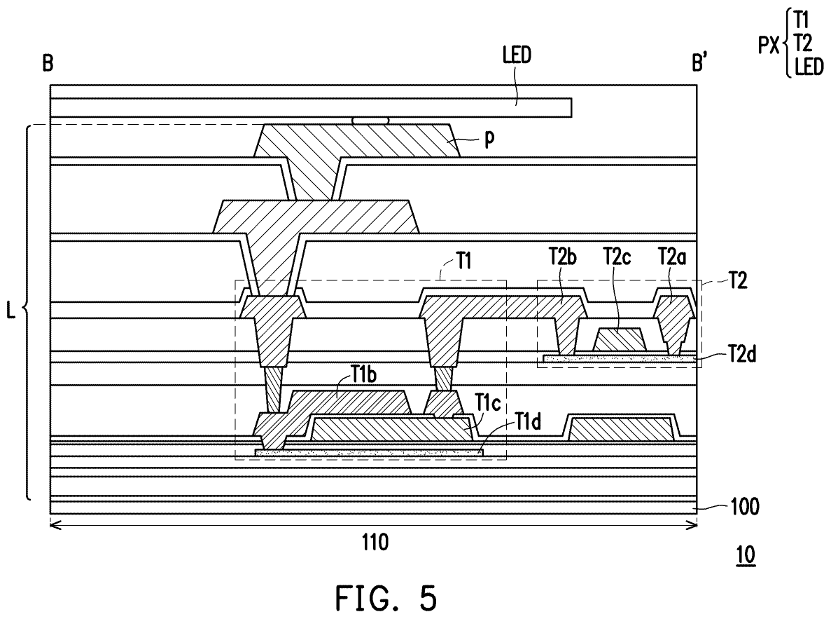

FIG. 3 is a top view and enlarged schematic diagram of a stretchable pixel array substrate 10 according to an embodiment of this disclosure. In particular, FIG. 3 corresponds to the structural unit U in FIG. 2, FIG. 4 and FIG. 5 are schematic cross-sectional views of a stretchable pixel array substrate 10 according to an embodiment of this disclosure. In particular, FIG. 4 and FIG. 5 correspond to a line segment A-A′ and a line segment B-B′ in FIG. 3 respectively.

Referring to FIG. 2, FIG. 3, FIG. 4 and FIG. 5, the stretchable pixel array substrate 10 further includes a component layer L disposed on the active area 110 of the base 100 (marked in FIGS. 4 and 5). The component layer L has pixel structures PX. Each of the pixel structures PX includes pixel transistors T1 and light emitting elements LED electrically connected to the pixel transistors T1. In some embodiments, the light emitting elements LED of each of the pixel structures PX may include a plurality of light emitting elements LED respectively used to emit a first color light, a second color light and a third color light. In some embodiments, the first color light, the second color light and the third color light are, for example, red light, green light and blue light respectively, but this disclosure is not limited to thereto.

In some embodiments, the pixel transistor T1 of each of the pixel structures PX has a first terminal (not shown), a second terminal T1b, a control terminal T1c, and a semiconductor pattern T1d. The first terminal (not shown) and the second terminal T1b of the pixel transistor T1 is electrically connected to two different areas of the semiconductor pattern T1d respectively, a pad p is electrically connected to the second terminal T1b of the first transistor T1, and the electrode (not shown) of the light emitting element LED is electrically connected to the pad p. In some embodiments, each of the pixel structures PX may also optionally include another pixel transistor T2, wherein the pixel transistor T2 has a first terminal T2a, a second terminal T2b, a control terminal T2c and a semiconductor pattern T2d, and the first terminal T2a and the second terminal T2b of the pixel transistor T2 are electrically connected to two different areas of the semiconductor pattern T2d respectively, and the second terminal T2b of the pixel transistor T2 is electrically connected to the control terminal T1c of the pixel transistor T1, but this disclosure is not limited to thereto.

Referring to FIG. 3 and FIG. 4, the component layer L of the stretchable pixel array substrate 10 further has a gate driving circuit 200. The gate driving circuit 200 is disposed on the active area 110 and is electrically connected to the pixel structures PX. Specifically, in this embodiment, each of the pixel structures PX further includes a scan line (not shown), wherein the scan line is electrically connected to the control terminal T2c of the pixel transistor T2 of the aforementioned pixel structures PX, and the gate driving circuit 200 is electrically connected to the scan line.

Referring to FIG. 2, FIG. 3, FIG. 4 and FIG. 5, the first islands 114 of the active area 110 of the base 100, the second islands 116 of the active area 110 of the base 100, the first islands 110 of the active area 110 of the base 100, the first bridges 118 of the active area 110 of the base 100, the pixel structures PX and the gate driving circuit 200 include structural units U. Each of the structural units U includes a first islands 114, a second islands 116 adjacent to the first islands 114, a first bridges 118 connected between the first islands 114 and the second islands 116, p pixel structures PX disposed on the first islands 114 and the second islands 116 and the driving transistor T3 at least disposed on the gate driving circuit 200 of the first islands 114, p is a positive integer, 1≤p≤6, the driving transistor T3 of the gate driving circuit 200 and a pixel transistor T1 of at least one pixel structure PX of the p pixel structures PX is disposed on the first islands 114, and a pixel transistor T1 of at least another pixel structure PX of the p pixel structures PX is disposed on the second islands 116.

For example, in some embodiments, three pixel structures PX may be selectively disposed on a first island 114 and a second island 116 of a structural unit U, that is, p=3, but this disclosure is not limited to there. In some embodiments, each of the structural units U may further include another second island 116 and another first bridge 118. That is to say, each of the structural units U may include a first islands 114, two second islands 116 and two first bridges 118 respectively disposed on both sides of the first islands 114, wherein each of the first bridges 118 is connected between a first island 114 and a corresponding second island 116; 4 pixel structures PX may optionally be disposed on a first island 114 and two second islands 116 of a structural unit U, namely p=4; but this disclosure is not limited to thereto.

Referring to FIG. 1, FIG. 2, FIG. 3 and FIG. 4, it is worth noting that the driving transistor T3 of the gate driving circuit 200 and the pixel transistor T1 of the pixel structures PX are disposed on the same first islands 114 of the active area 110 of the base 100, the driving transistor T3 of gate driving circuit 200 is not disposed in a peripheral area having the edge 100e1, 100e2 of base 100. That is to say, when the stretchable pixel array substrate 10 is bent, the driving transistor T3 of the gate driving circuit 200 and the pixel transistor T1 of the pixel structures PX are both disposed on the active area 110 with a smaller stress, and the driving transistor of the gate driving circuit 200 and the pixel transistor T1 of the pixel structures PX are both not easily damaged, thereby improving stretchability.

In some embodiments, preferably, the driving transistor T3 of the gate driving circuit 200 is disposed on the first stress sub-region 110a on which the stress is smaller in the active area 110. In some embodiments, the first stress sub-region 110a has a strain value σ, −0.040%<σ<0.030%, and the pixel transistor T1 and driving transistor T3 located on the first stress sub-region 110a can work normally. The first stress sub-region 110a includes a minimum stress region 110a-1, the minimum stress region 110a-1 has a first boundary e1 and a second boundary e2 opposite to each other, the first boundary e1 and the second boundary e2 are respectively located on the opposite sides of the first central axis x1, a distance a1 in the first direction x between the first boundary e1 of the minimum stress region 110a-1 and the first central axis x1 is less than or equal to one-tenth of the first width L1, and the distance a2 in the first direction x between the second boundary e2 of the minimum stress region 110a-1 and the first central axis x1 is less than or equal to one-tenth of the first width L1. In some embodiments, preferably, the driving transistor T3 of the gate driving circuit 200 is disposed in the minimum stress region 110a-1.

Referring to FIG. 2, in some embodiments, the first islands 114 and second islands 116 of each of the structural units U are arranged in the first direction x, and the p pixel structures PX of the structural unit U include two adjacent first pixel structures PX1 disposed on the first islands 114, light emitting elements LED of the two adjacent first pixel structures PX1 have a first distance d1 in the first direction x, the p pixel structures PX of the structural unit U include a second pixel structure PX2 disposed on the second islands 116, the p pixel structures PX of the structural unit U include a second pixel structure PX2 dispose on the second islands 116, the light emitting element LED of the second pixel structures PX2 and the light emitting element LED of the two first pixel structures PX1 have a second distance d2 in the first direction x, and the first distance d1 and the second distance d2 are substantially equal.

Referring to FIG. 2, in some embodiments, the structural units U are arranged into structural unit column CU, the structural unit column CU are arranged in the first direction x, the second islands 116 of one structural unit column CU is disposed adjacent to the second islands 116 of the next structural unit column CU, the light emitting element LED of the second pixel structures PX2 on the second islands 116 of the structural unit column CU and the light emitting element LED of the second pixel structures PX2 on the second islands 116 of the next structural unit column CU has a third distance d3 in the first direction x, and the first distance d1, the second distance d2 and the third distance d3 are substantially equal.

Referring to FIG. 2, in some embodiments, the structural units U are arranged into structural unit rows RU, and the structural unit rows RU are arranged in the second direction y intersected with the first direction x, the first islands 114 of one structural unit rows RU are disposed adjacent to the first islands 114 of the next structural unit row RU, and the second island 116 of the structural unit row RU are adjacent to the second island 116 of the next structural unit row RU disposed, the light emitting element LED of the first pixel structures PX1 on the first island 114 of the structural unit row RU and the light emitting element LED of the first pixel structures PX1 on the first island 114 of the next structural unit row RU have a fourth distance d4 in the second direction y, and the first distance d1 and the fourth distance d4 are essentially equal. In some embodiments, the light emitting element LED of the second pixel structures PX2 on the second island 116 of the structural unit row RU and the light emitting element LED of the second pixel structures PX2 on the second islands 116 of the next structural unit row RU have a fifth distance d5 in the second direction y, and the first distance d1 and the fifth distance d5 are substantially equal.

In some embodiments, one structural unit column CU and the next structural unit column CU may be mirror images of each other. In some embodiments, one structural unit row RU and the next structural unit row RU may be mirror images of each other.

In some embodiments, a sum of a length in the first direction x of a first island 114 and a length in the first direction x of a first bridges 118 adjacent to the first island 114 is a length l2, a sum of a length in the first direction x of a second island 116 and a length in the first direction x of a first bridges 118 adjacent to second island 116 is a length l1, l2=n·l1, where n is a positive integer, and 1>n≥2.

Referring to FIG. 3 and FIG. 4, in some embodiments, the first island 114 has an upper edge 114a, a lower edge 114b, a first side edge 114c and a second side edge 114d, the upper edge 114 is disposed opposite to the lower edge 114b, the first side edge 114c is connected between the upper edge 114a and the lower edge 114b, the second side edge 114d is disposed opposite the first side edge 114c and connected between the upper edge 114a and the lower edge 114b, a length K1 of the upper edge 114a is greater than or equal to the length K2 of lower edge 114b, the length K3 of the first side edge 114c and the length K4 of the second side edge 114d are less than the length K2 of the lower edge 114b, and the driving transistor T3 of the gate driving circuit 200 and the pixel transistor T1 of at least one pixel structure PX are arranged along the upper edge 114a of the first islands 114.

Referring to FIG. 3, in some embodiments, the second island 116 has one side 116 adjacent to the first island 114, and the side 116a of the second island 116 and the first side edge 114c of the first islands 114 form an acute angle θ. For example, in some embodiments, 8°≤θ≤40°; preferably, 10°≤θ≤35°, but this disclosure is not limited to thereto.

In the following embodiment, the reference numerals and part of the description of the foregoing embodiment are applied, where the same reference numerals are used to indicate the same or similar components, and descriptions of the same technical contents are omitted. Reference may be made to the foregoing embodiment for the omitted descriptions, which will not be repeated in following embodiment.

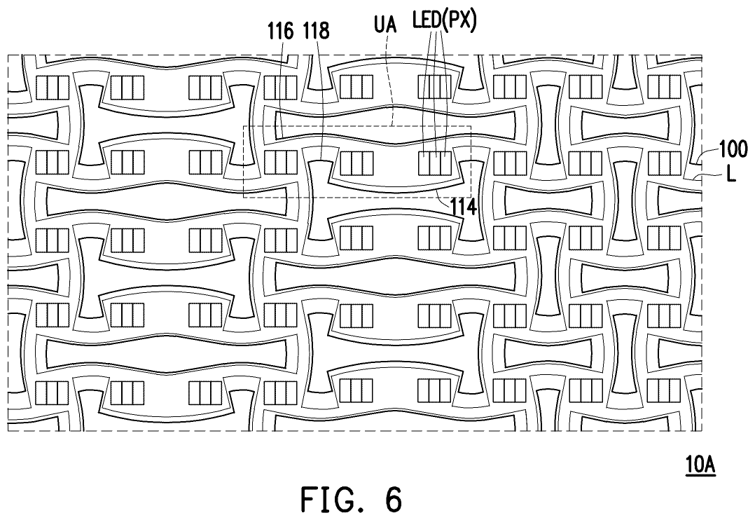

FIG. 6 is a top view of a part of the stretchable pixel array substrate 10A according to another embodiment of the present disclosure. The stretchable pixel array substrate 10A in FIG. 6 is similar to the stretchable pixel array substrate 10 in FIG. 2. The difference between the two is that their structural units U and UA are different. Specifically, compared with the structural unit U in FIG. 2, the structural unit U in FIG. 6 lacks a first bridge 118 and a second island 116.

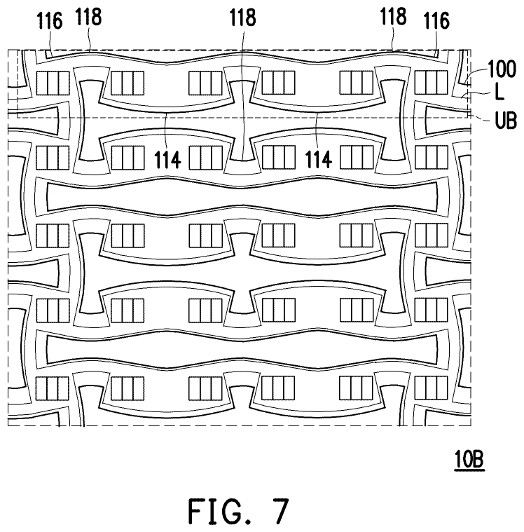

FIG. 7 is a top view of a part of the stretchable pixel array substrate 10B according to another embodiment of the present disclosure. The stretchable pixel array substrate 10B in FIG. 7 is similar to the stretchable pixel array substrate 10 in FIG. 2. The difference between the two is that their structural units U and UB are different. Specifically, compared with the structural unit U in FIG. 2, the structural unit UB in FIG. 6 has an additional first bridge 118 and an additional first island 114. That is to say, the structural unit UB in FIG. 6 includes two second islands 116, two first islands 114 disposed between the two second islands 116, and three first bridges 118.

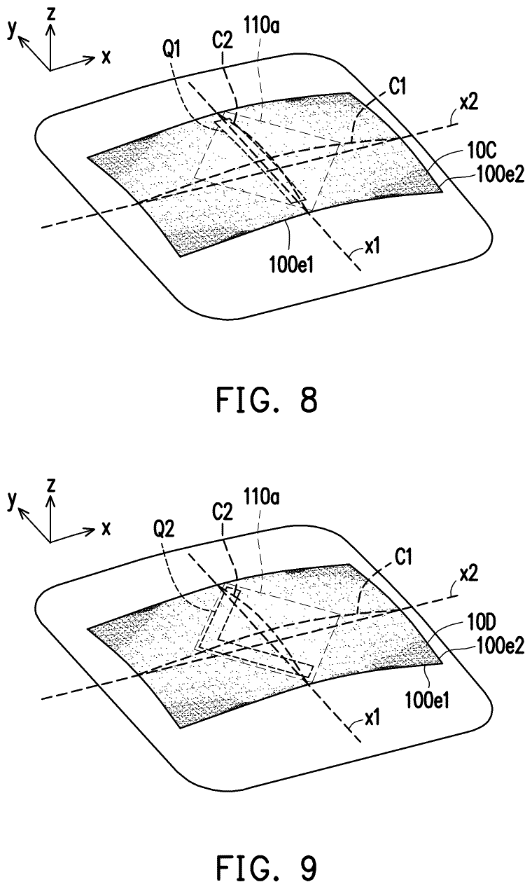

FIG. 8 is a three-dimensional schematic diagram of a stretchable pixel array substrate 10C according to yet another embodiment of the present disclosure. In particular, FIG. 8 shows the stretchable pixel array substrate 10C in a curved state and the stress distribution on it. The denser the points, the greater the stress on it, and the sparser the points, the smaller the stress.

The stretchable pixel array substrate 10C of FIG. 8 is similar to the stretchable pixel array substrate 10 of FIG. 1. The difference between the two is that in the embodiment of FIG. 8, The difference between the first radius of curvature of the first cut line C1 and the second radius of the second cut line C2 is larger, and the first stress sub-region 110a with smaller stress may be a rhombus region, and the boundaries of the rhombus region are not parallel to the two adjacent edges 100e1, 100e2 of base 100. In the embodiment of FIG. 8, the first islands 114 with the pixel transistor T1 and the driving transistor T3 of the gate driving circuit 200 (refer to FIG. 4) may be arranged along the first central axis x1 and disposed in a region Q1 of the first stress sub-region 110a, wherein the first central axis x1 is parallel to the shorter edge 100e2 of base 100.

FIG. 9 is a three-dimensional schematic diagram of a stretchable pixel array substrate 10D according to an embodiment of this disclosure. In particular, FIG. 9 shows the stretchable pixel array substrate 10D in a curved state and the stress distribution thereon. The denser the points, the greater the stress thereon, and the sparser the points, the smaller the stress thereon. The stretchable pixel array substrate 10D of FIG. 9 is similar to the stretchable pixel array substrate 10C of FIG. 8. The difference between the two is that in the embodiment of FIG. 9, first islands 114 (refer to FIG. 4) with the pixel transistor T1 and the driving transistor T3 of the gate driving circuit 200 may be arranged along two adjacent boundaries of the rhombus-shaped first stress sub-region 110a and disposed in a region Q2 of the first stress sub-region 110a.

FIG. 10 is a three-dimensional schematic diagram of a stretchable pixel array substrate 10E according to another embodiment of the present disclosure. In particular, FIG. 10 shows the stretchable pixel array substrate 10E in a curved state and the stress distribution thereon. The denser the points, the greater the stress thereon, and the sparser the points, the smaller the stress thereon. The stretchable pixel array substrate 10E of FIG. 10 is similar to the stretchable pixel array substrate 10C of FIG. 8. The difference between the two is that in the embodiment of FIG. 10, first islands 114 (please refer to FIG. 4) with pixel transistor T1 and driving transistor T3 of gate driving circuit 200 may be arranged along two opposite boundaries of the rhombus-shaped first stress sub-region 110a and disposed in a region Q3.

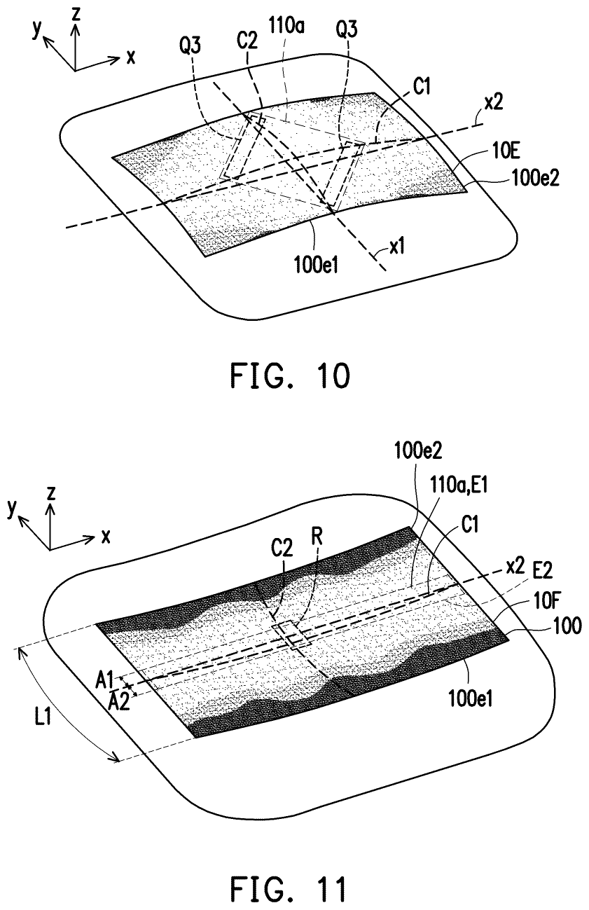

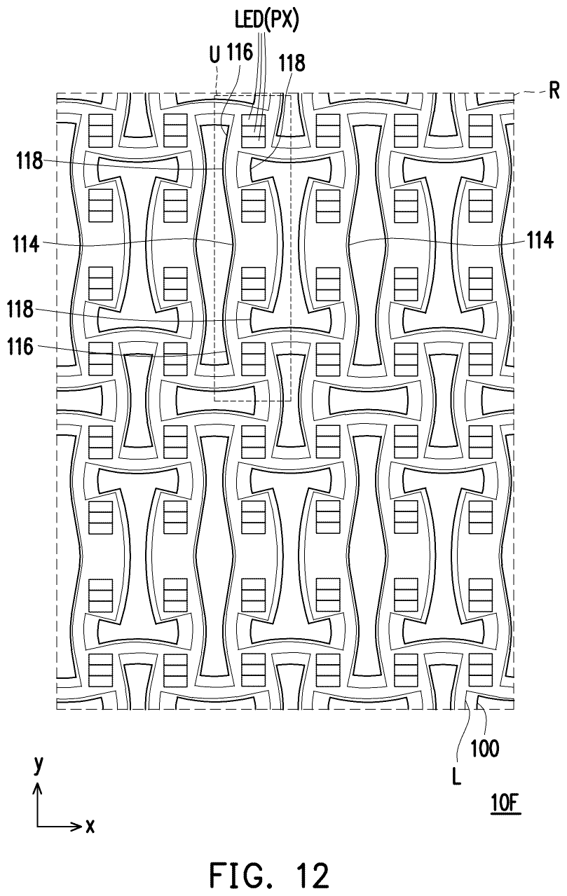

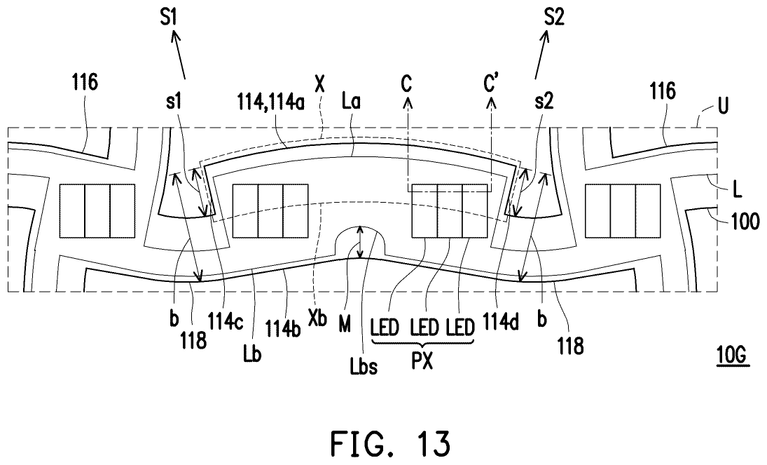

FIG. 11 is a three-dimensional schematic diagram of a stretchable pixel array substrate 10F according to another embodiment of the present disclosure. In particular, FIG. 11 shows the stretchable pixel array substrate 10F in a curved state and the stress distribution thereon. The denser the points, the greater the stress thereon, and the sparser the points, the smaller the stress thereon. FIG. 12 is a schematic top view of a part R of the stretchable pixel array substrate 10F according to another embodiment of the present disclosure. FIG. 12 corresponds to the part R of FIG. 11.

The stretchable pixel array substrate 10F of FIGS. 11 and 12 is similar to the stretchable pixel array substrate 10 of FIGS. 1 and 2. The difference between the two is that the bending methods of the two are different. Referring to FIG. 11, specifically, in some embodiments, the stretchable pixel array substrate 10F is bent in the first direction x and the second direction y, and the stretchable pixel array substrate 10F is cut out by the xz plane where the first direction x and the third direction z are located to obtain a first cut line C1, the first cut line C1 has a first radius of curvature and is recessed in the opposite direction of the third direction z, the stretchable pixel array substrate 10F is cut out by the yz plane where the second direction y and the third direction z is located to obtain a second cut line C2, the second cut line C2 has a second radius of curvature and is depressed toward the opposite direction of third direction z, and the first radius of curvature is greater than the second radius of curvature. In short, the stretchable pixel array substrate 10F has a double curvature concave curved surface.

Referring to FIGS. 11 and 12, the base 100 of the stretchable pixel array substrate 10F has a second central axis x2, the second direction y is intersected with the second central axis x2, the active area 110 includes a first stress sub-region 110a with first islands 114, the first stress sub-region 110a has a first boundary E1 and a second boundary E2 opposite to each other, the first boundary E1 and the second boundary E2 are respectively located on opposite sides of the second central axis x2, the distance A1 in the second direction y between the first boundary E1 of the first stress sub-region 110a and the second central axis x2 is less than or equal to one-half of the second width L2, and the distance A2 between the second boundary E2 of the first stress sub-region 110a and the second central axis x2 in the second direction y is less than or equal to one-half of the second width L2, and the distance A2 in the second direction y between the second boundary E2 of the first stress sub-region 110a and the second central axis x2 is less than or equal to one-half of the second width L2. More preferably, the distance A1 in the second direction y between the first boundary E1 of the first stress sub-region 110a and the second central axis x2 is less than or equal to one-tenth of the second width L2, and the distance A2 in the second direction y between the second boundary E2 of the first stress sub-region 110a and the second central axis x2 is less than or equal to one-tenth of the second width L2.

Referring to FIGS. 11 and 12, in addition, in this embodiment, the first islands 114 and the second islands 116 of the same structural unit U are arranged in the second direction y parallel to the shorter edge 100e2 of the base 100. First islands 114 of the structural units U are arranged in the first direction x parallel to the longer edge 100e1 of the base 100.

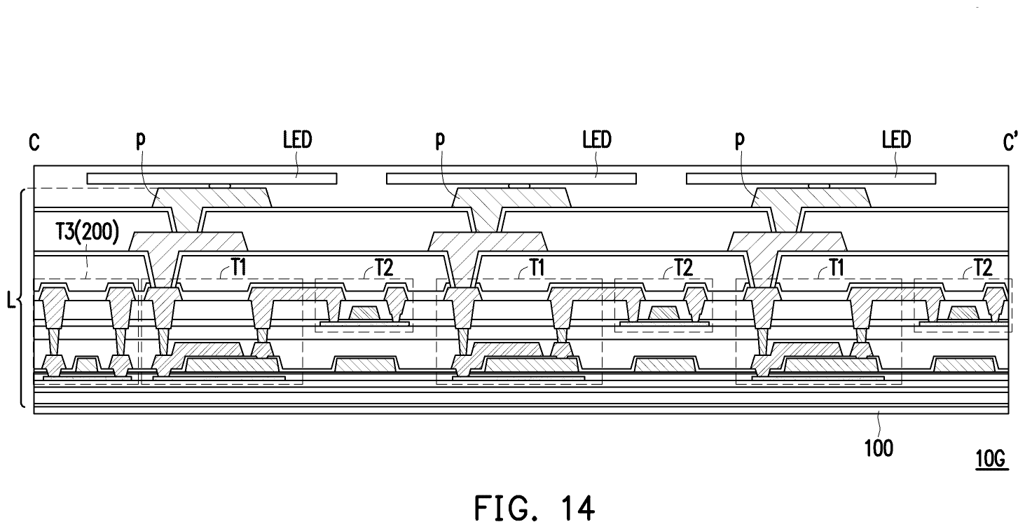

FIG. 13 is a top view of a part of the stretchable pixel array substrate 10G according to yet another embodiment of this disclosure. FIG. 14 is a schematic cross-sectional view of a stretchable pixel array substrate 10G according to yet another embodiment of this disclosure. In particular, FIG. 14 corresponds to line segment C-C′ in FIG. 13. The stretchable pixel array substrate 10G in FIGS. 13 and 14 is similar to the stretchable pixel array substrate 10 in FIGS. 3 and 4. The differences between the two are as follows.

In the embodiments of FIG. 13 and FIG. 14, a part of the component layer L is disposed on the first islands 114 and includes the pixel transistor T1 of the pixel structures PX and the driving transistor T3 of the gate driving circuit 200, the part of the component layer L has a first edge La and a second edge Lb opposite to each other, the first edge La and the second edge Lb are respectively adjacent to the upper edge 114a and lower edge 114b of the first islands 114 of the base 100, and the second edge Lb of the part of the component layer L has an arc structure Lbs that is depressed toward the first edge La. The distance M between the arc structure Lbs and the lower edge 114b of the first islands 114 of base 100 gradually changes as it moves away from the first side edge 114c of the first islands 114 of the base 100. Specifically, the distance M between the arc structure Lbs and the lower edge 114b of the first islands 114 of the base 100 gradually increases and then decreases as it moves away from the first side edge 114c of the first islands 114 of the base 100. The arc structure lbs is a strain resistant design. Through the arc structure Lbs, the stretchable performance of stretchable pixel array substrate 10G is further improved.

Referring to FIG. 13, in addition, in this embodiment, the first islands 114 has a width b in the first side edge direction S1 parallel to the first side edge 114c, and the first islands 114 has a region X, the region X bounded by the upper edge 114a, a part of the first side edge 114c, a part of the second side edge 114d, and a dummy lower edge Xb connecting the part of the first side edge 114c and the part of the second side edge 114d, the part of the first side edge 114c of the region X has a width s1 in the first side edge direction S1, the part of the second side edge 114d of the region X has a width s2 in a second side edge direction S2 parallel to the second side edge 114d,

$$s 1 \leq \frac{2}{3} b ,$$

$$s 2 \leq \frac{2}{3} b ,$$

and the driving transistor T3 of the gate driving circuit 200 and the pixel transistor T1 of the at least one pixel structure PX are disposed in the region X. In this way, the pixel transistor T1 of the pixel structures PX and the driving transistor T3 of the gate driving circuit 200 can avoid the stress concentration area, thereby improving the stretchability of the stretchable pixel array substrate 10G. In this way, the pixel transistor T1 of the pixel structures PX and the driving transistor T3 of the gate driving circuit 200 can avoid to disposed in the stress concentration area, thereby improving the stretchability of the stretchable pixel array substrate 10G.

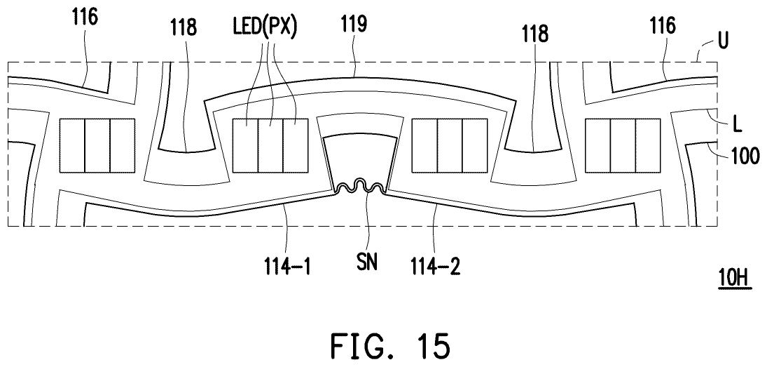

FIG. 15 is a top view of a part of the stretchable pixel array substrate 10H according to an embodiment of this disclosure. Referring to FIG. 15, in this embodiment, the first islands 114 with a large area include a first portion 114-1 and a second portion 114-2; the base 100 further has a second bridge 119, and the second bridge 119 is connected between the first portion 114-1 of the first islands 114 and the second portion 114-2 of the first islands 114; the base 100 further has an auxiliary structure SN disposed opposite the second bridge 119 and connected between the first portion 114-1 and the second portion 114-2 of the first islands 114. The auxiliary structure SN is another strain-resistant design. Through the auxiliary structure SN, the stretchable performance of the stretchable pixel array substrate 10H is further improved. In this embodiment, the auxiliary structure SN is, for example, serpentine-shaped. However, this disclosure is not limited to thereto. In other embodiments, the auxiliary structure SN may be in the shape of a bridge, an arc, or other shapes.

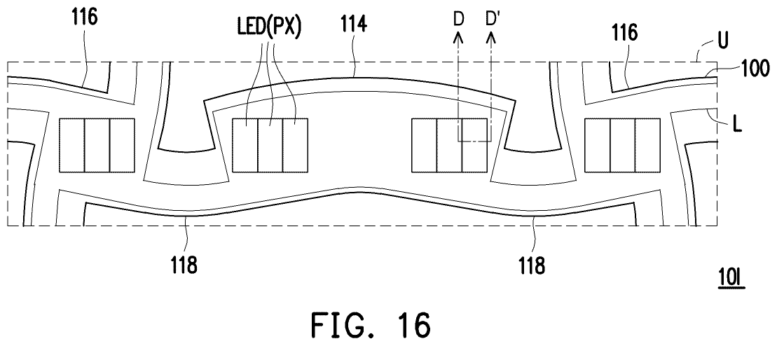

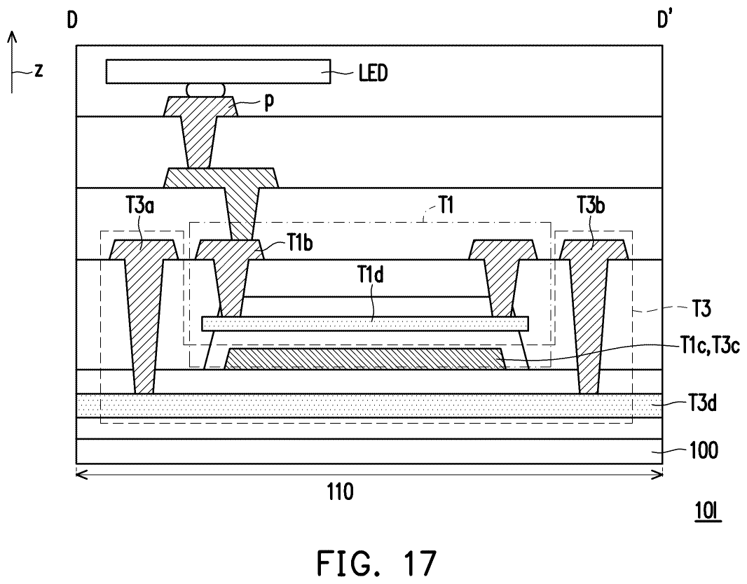

FIG. 16 is a top view of a part of a stretchable pixel array substrate 10I according to another embodiment of the present disclosure. FIG. 17 is a schematic cross-sectional view of a stretchable pixel array substrate 10I according to another embodiment of the present disclosure. In particular, FIG. 17 corresponds to line segment D-D′ in FIG. 16. The stretchable pixel array substrate 10I of FIGS. 16 and 17 is similar to the stretchable pixel array substrate 10 of FIGS. 3 and 4. The difference between the two is: in the embodiment of FIG. 16 and FIG. 17, the driving transistor T3 has a first terminal T3a, a second terminal T3b, a control terminal T3c, and a semiconductor pattern T3d, the first terminal T3a and the second terminal T3b of the driving transistor T3 are electrically connected to two different areas of the semiconductor pattern T3d respectively, in particular, the semiconductor pattern T3d of the driving transistor T3 overlaps with the semiconductor pattern T1d of the pixel transistor T1 of the pixel structures PX in the third direction z substantially perpendicular to the base 100. In this way, even if the driving transistor T3 of the gate driving circuit 200 and the pixel transistor T1 of the pixel structures PX are disposed on the first islands 114 of the active area 110, the driving transistor T3 of the gate driving circuit 200 will not occupy too much area of the first islands 114 and will not easily affect the resolution of the stretchable pixel array substrate 10I. In addition, in the embodiments of FIG. 16 and FIG. 17, the control terminal T3c of the driving transistor T3 and the control terminal T1c of the pixel transistor T1 may share the same conductive pattern.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A stretchable pixel array substrate comprising:
a base having an active area, wherein the active area has openings to define first islands, second islands and first bridges of the active area, an area of each of the first islands is larger than an area of each of the second islands, and at least one part of the first bridges is connected between the first islands and the second islands;
a plurality of pixel structures disposed on the active area of the base, wherein each of the pixel structures comprises a pixel transistor and a light emitting element electrically connected to the pixel transistor; and
a gate driving circuit disposed on the active area and electrically connected to the pixel structures;
wherein the first islands of the active area of the base, the second islands of the active area of the base, the first bridges of the active area of the base, the pixel structures and the gate driving circuit comprise structural units;
each of the structural unit comprises a first island, a second island adjacent to the first island, a first bridge connecting between the first island and the second island, p pixel structures of the pixel structures disposed on the first island and the second island and a driving transistor at least disposed in the gate driving circuit of the first island, p is a positive integer, 1≤p≤6, and the driving transistor of the gate driving circuit and the pixel transistor of at least one pixel structure of the p pixel structures are disposed on the first island.

2. The stretchable pixel array substrate according to claim 1, wherein the first island and the second island of each of the structural units are arranged in a first direction, and the p pixel structures comprise two adjacent first pixel structures disposed on the first island, the light emitting elements of the two adjacent first pixel structures have a first distance in the first direction, the p pixel structures comprise a second pixel structure disposed on the second island, the light emitting element of the second pixel structures and the light emitting element of the two first pixel structures have a second distance in the first direction, and the first distance and the second distance are substantially equal.

3. The stretchable pixel array substrate according to claim 2, wherein the structural units are arranged in structural unit columns, the structural unit columns are arranged in the first direction, the second island of a structural unit column is disposed adjacent to the second island of a next structural unit column, the light emitting element of the second pixel structure on the second island of the structural unit column and the light emitting element of the second pixel structure on the second island of the next structural unit column have a third distance in the first direction, and the first distance, the second distance and the third distance are substantially equal.

4. The stretchable pixel array substrate according to claim 1, wherein the first island and the second island of each of the structural units are arranged in a first direction, the p pixel structures comprise two adjacent first pixel structures disposed on the first island, light emitting elements of the two first pixel structures have a first distance in the first direction; the structural units are arranged in structural unit rows, the structural unit rows are arranged in a second direction intersecting with the first direction, the first island of a structural unit row is disposed adjacent to the first island of a next structural unit row, the second island of the structural unit row is disposed adjacent to the second island of the next structural unit row, the light emitting element of the first pixel structure on the first island of the structural unit row and the light emitting element of the first pixel structure on the first island of the next structural unit row have a fourth distance in the second direction, and the first distance and the fourth distance are substantially equal.

5. The stretchable pixel array substrate according to claim 1, wherein each of the first islands has an upper edge, a lower edge, a first side edge and a second side edge, the upper edge is disposed opposite the lower edge, the first side edge is connected between the upper edge and the lower edge, the second side edge is disposed opposite to the first side edge and connected between the upper edge and the lower edge, a length of the upper edge is greater than or equal to a length of the lower edge, a length of the first side edge and a length of the second side edge are less than the length of the lower edge, and a driving transistor of the gate driving circuit and the pixel transistor of at least one pixel structure of the p pixel structures are arranged along the upper edge of the first island.

6. The stretchable pixel array substrate according to claim 5, wherein the first island has a width b in a first side edge direction parallel to the first side edge, the first island has a region, the region is bounded by the upper edge, a part of the first side edge, a part of the second side edge, and a dummy lower edge connecting the part of the first side edge and the part of the second side edge, the part of the first side edge of the region has a width s1 in the first side edge direction, the portion of the second side edge of the region has a width s2 in a second side edge direction parallel to the second side edge,
$$s 1 \leq \frac{2}{3} b ,$$
$$s 2 \leq \frac{2}{3} b ,$$
and the driving transistor of the gate driving circuit and the pixel transistor of the at least one pixel structure of the p pixel structures are disposed in the region.

7. The stretchable pixel array substrate according to claim 1, wherein the first island and the second island of each of the structural units are arranged in a first direction; the structural units are arranged in structural unit columns, the structural unit columns are arranged in the first direction, and one structural unit column and a next structural unit column are mirror images of each other.

8. The stretchable pixel array substrate according to claim 1, wherein the first island and the second island of each of the structural units are arranged in a first direction; the structural units are arranged in structural unit rows, the structural unit rows are arranged in a second direction intersecting with the first direction, and a structural unit row and a next structural unit row are mirror images of each other.

9. The stretchable pixel array substrate according to claim 1, wherein a semiconductor pattern of the driving transistor overlaps with a semiconductor pattern of the pixel transistor of the at least one pixel structure of the p pixel structures in a third direction substantially perpendicular to the base.

10. The stretchable pixel array substrate according to claim 1, wherein the base has a first central axis, a first direction is perpendicular to the first central axis, the base has a first width in the first direction, the active area includes a first stress sub-region having the first islands, the first stress sub-region has a first boundary and a second boundary opposite to each other, the first boundary and the second boundary are respectively located on opposite sides of the first central axis, the distance between the first boundary of the first stress sub-region and the first central axis in the first direction is less than or equal to one quarter of the first width, and a distance between the second boundary of the first stress sub-region and the first central axis in the first direction is less than or equal to one quarter of the first width.
